(19) United States
(12) Patent Application Publication
(10) Pub. No.: US 2007/0085211 A1
(43) Pub. Date: Apr. 19, 2007

(54) Semiconductor device and method for manufacturing the same

(76) Inventor: Masakazu Hamada, Osaka (JP)

Correspondence Address: MCDERMOTT WILL & EMERY LLP, 600 13TH STREET, N.W., WASHINGTON, DC, 20005-3096, US

(21) Appl. No.: 11/483,668

(22) Filed: Jul. 11, 2006

(30) Foreign Application Priority Data
Oct. 13, 2005 (JP) 2005-299398

(51) Int. Cl. H01L 23/52

(52) U.S. Cl. 257/758

(57) ABSTRACT

A second interlayer insulating film is formed on a first interlayer insulating film and a wiring including a Cu film, and a via and a trench are formed in the second interlayer insulating film so as to expose the Cu film. After a hollow having an inner diameter larger than that of the via is formed in the Cu film, a first barrier metal film is formed. Subsequently, the first barrier metal film is re-sputtered to fill the hollow with the first barrier metal film and to extend the via so as to have a rounded lower part. Next, a second barrier metal film and a Cu film are formed sequentially in the via and the trench. Then, the Cu film, the second barrier metal film, and the first barrier metal film on the second interlayer insulating film are removed.

### BACKGROUND ART

1. Field of the Invention

The present invention relates to a semiconductor device and a method for manufacturing it, and particularly relates to a method for forming a barrier film in damascene wiring formation.

2. Description of the Prior Art

A recent increase in integration of semiconductor devices offers inevitable problems of enhancing a micro processing technique and a reliability ensuring technique. Improvements in a technique for processing a damascene wiring using copper (Cu) and in a technique for forming a metal film are essential in a wiring formation process for a semiconductor device.

A barrier meal film, which is formed for preventing Cu diffusion, is desired to be thin for low wiring resistance while being desired to be thick for suppressing deficiency such as stress migration. Techniques for satisfying these conflicting desires are demanded in the art of the barrier metal film. Under the circumstances, recently, a process is proposed in which a barrier metal film is thinned at the bottom while being thickened at a via side wall.

FIG. 6A to FIG. 6I are sections for explaining a conventional semiconductor device manufacturing method.

First, as shown in FIG. 6A, a first interlayer insulating film 501 is formed on a semiconductor substrate 500. A first wiring 503 formed of a first barrier metal film (not shown) and a first Cu film 502 is formed in the first interlayer insulating film 501. Then, a liner insulting film 504 and a second interlayer insulating film 505 are formed sequentially on the first interlayer insulating film 501 and the first wiring 503.

Subsequently, as shown in FIG. 6B, part of the second interlayer insulating film 505 is removed by dry etching to expose the liner insulating film 504.

Next, as shown in FIG. 6C, a region of the second interlayer insulating film 505 including part above part where the liner insulating film 504 is exposed is removed by dry etching to form a trench 506.

Thereafter, as shown in FIG. 6D, the exposed part of the liner insulating film 504 is removed by dry etching to form a via 507 with the first Cu film 502 exposed.

Subsequently, as shown in FIG. 6E, a second barrier metal film 508 is formed by sputtering so as to cover the via 507 and the trench 506. In this sputtering, the second barrier metal film 508 is formed also on the first Cu film 502 exposed through the via 507.

Next, as shown in FIG. 6F, the second barrier metal film 508 on the first Cu film 502 is removed by sputtering to expose the first Cu film 502 again.

Thereafter, as shown in FIG. 6G, a third barrier metal film 509 is formed by sputtering so as to cover the via 507 and the trench 506.

Subsequently, as shown in FIG. 6H, a second Cu film 510 is formed on the third barrier film 509 so as to fill the via 507 and the trench 506. Then, the second Cu film 510, the third barrier metal film 509, and the second barrier metal film 508 are polished by chemical mechanical polishing (CMP) until the upper face of the second interlayer insulating film 505 is exposed, thereby forming a plug 511 and a second wiring 512 which are formed of the second barrier metal film 508, the third barrier metal film 509, and the second Cu film 510, as shown in FIG. 6I.

In the above conventional semiconductor device manufacturing method, only the third barrier metal film 509 is formed on the first Cu film 502, attaining a thinned barrier metal film at a contact part between the first wiring 503 and the plug 511.

### SUMMARY OF THE INVENTION

In the conventional semiconductor device manufacturing method, however, the second barrier metal film 508 and the third barrier metal film 509 are formed at the side wall of the plug 511, and the total film thickness of the barrier metal films increases at the lower part of the side wall of the plug 511. Accordingly, the contact area between the first Cu film 502 and the second Cu film 510 (the contact area of the second Cu film 510 where it faces the first Cu film 502 with the second barrier film 508 interposed) becomes small. This increases resistance at the contact part between the first wiring 503 and the plug 511 to invite lowering of resistance to stress migration and resistance to electro-migration, which are accompanied by the resistance increase.

The present invention has its object of providing a semiconductor device in which resistance between wirings and resistance between a wiring and a plug are reduced with resistance to stress migration and resistance to electro-migration ensured and providing a method for manufacturing it.

To attain the above object, a first semiconductor device according to the present invention includes: a fist insulting film formed on a semiconductor substrate; a first wiring formed in the first insulating film; a second insulting film formed on the first insulating film; and a plug formed in the second insulating film, wherein the plug is formed so as to stick in the first wiring and is formed of a first barrier film, a second barrier film, and a metal film, a hollow of which diameter is larger than that of the plug is formed in the first insulating film under the second insulating film, the first barrier film forms a side wall of the plug and fills the hollow, and the second barrier film is formed along the first barrier film so as to cover the metal film at the side wall of the plug and at a part where the plug is in contact with the first wiring.

With the above structure, the contact area between the first wiring and the second barrier film increases compared with that in the conventional semiconductor device, resulting in lowering of electric resistance between the wirings even in the case where the barrier films are made of materials having resistances higher than that of a film material of the wirings. Accordingly, deficiency such as stress migration, electro-migration, and the like can be suppressed.

Further, when part of the barrier film on the side face of the hollow is formed thicker than the other part, the resistance to stress migration and the resistance to electro-migration increase further.

A second semiconductor device according to the present invention includes: a first insulating film formed on a semiconductor substrate; a first wiring formed in the first insulating film; a second insulating film formed on the first insulating film; a third insulating film formed on the second insulating film; and a plug formed in the second insulating film and the third insulating film, wherein the plug is formed so as to stick in the first wiring and is formed of a first barrier film, a second barrier film, and a metal film, the second insulating film is set back largely from the periphery of the plug, the first barrier film forms a side wall of the plug and fills the setback part of the second insulating film, and the second barrier film is formed along the first barrier film so as to cover the metal film at the side wall of the plug and at a part where the plug is in contact with the first wiring.

With the above structure, the contact area between the first wiring and the second barrier film increases compared with that in the conventional semiconductor device, as well, resulting in lowering of electric resistance between the first wiring and the plug. Further, the plug can be formed in the first wiring deeper than the plug in the first semiconductor device, further increasing the contact area between the first wiring and the second barrier film to further reduce the electric resistance between the wiring and the plug.

A first method for manufacturing a semiconductor device according to the present invention, includes the steps of: (a) forming a first trench in a first insulating film formed on a semiconductor substrate and forming, in the first trench, a first wiring formed of a barrier film and a first metal film; (b) forming a second insulating film on the first insulating film; (c) forming a second trench by removing the second insulating film so as to expose the first metal film; (d) forming a hollow having a diameter larger than that of the second trench by removing an upper part of the first metal film which is exposed at the second trench; (e) forming a first barrier film so as to cover part of a bottom face of the hollow and a side face of the second trench; (f) depositing the first barrier film on a side face of the hollow by removing the first barrier film on the bottom face of the hollow; (g) forming a second barrier film so as to cover the hollow and the second trench over the first barrier film; (h) forming a second metal film so as to fill the hollow and the second trench over the second barrier film; and (i) forming a plug by removing the second metal film, the second barrier film, and the first barrier film so as to expose the second insulating film.

According to the above method, the contact area between the first wiring and the second barrier film where a current flows in operation increases. Therefore, by this method, the first semiconductor device in which the resistance to stress migration and the resistance to electro-migration increase can be manufactured.

A second method for manufacturing a semiconductor device according to the present invention includes the steps of: (a) forming a first trench in a first insulating film formed on a semiconductor substrate and forming, in the first trench, a first wiring formed of a barrier film and a first metal film; (b) forming, on the first insulating film, a second insulating film and a third insulating film sequentially; (c) forming a second trench by removing part of the second insulating film and the third insulating film so as to expose the first metal film; (d) forming a hollow having a diameter larger than that of the second trench by setting back the second insulating film; (e) forming a first barrier film so as to cover a bottom face of the hollow and a side face of the second trench; (f) depositing the first barrier film on a side face of the hollow by removing the first barrier film on the bottom face of the hollow; (g) forming a second barrier film so as to cover the hollow and the second trench over the first barrier film; (h) forming a second metal film so as to fill the hollow and the second trench over the second barrier film; and (i) forming a plug by removing the second metal film, the second barrier film, and the first barrier film so as to expose the second insulating film.

According to the above method, the contact area between the first wiring and the second barrier film where a current flows in operation increases. Therefore, by this method, the second semiconductor device in which the resistance to stress migration and the resistance to electro-migration increase can be manufactured.

### BRIEF DESCRIPTION OF THE DRAWINGS

FIG. 1 is a section showing a semiconductor device according to Embodiment 1 of the present invention.

FIG. 2A to FIG. 2K are sections showing a semiconductor device manufacturing method according to Embodiment 1.

FIG. 3A and FIG. 3B are sections in enlarged scale showing the semiconductor device according to Embodiment 1 after the steps shown in FIG. 2G and FIG. 21, respectively.

FIG. 4 is a section showing a semiconductor device according to Embodiment 2 of the present invention.

FIG. 5A to FIG. 5J are sections showing a semiconductor device manufacturing method according to Embodiment 2 of the present invention.

FIG. 6A to FIG. 6I are sections for explaining the conventional semiconductor device manufacturing method.

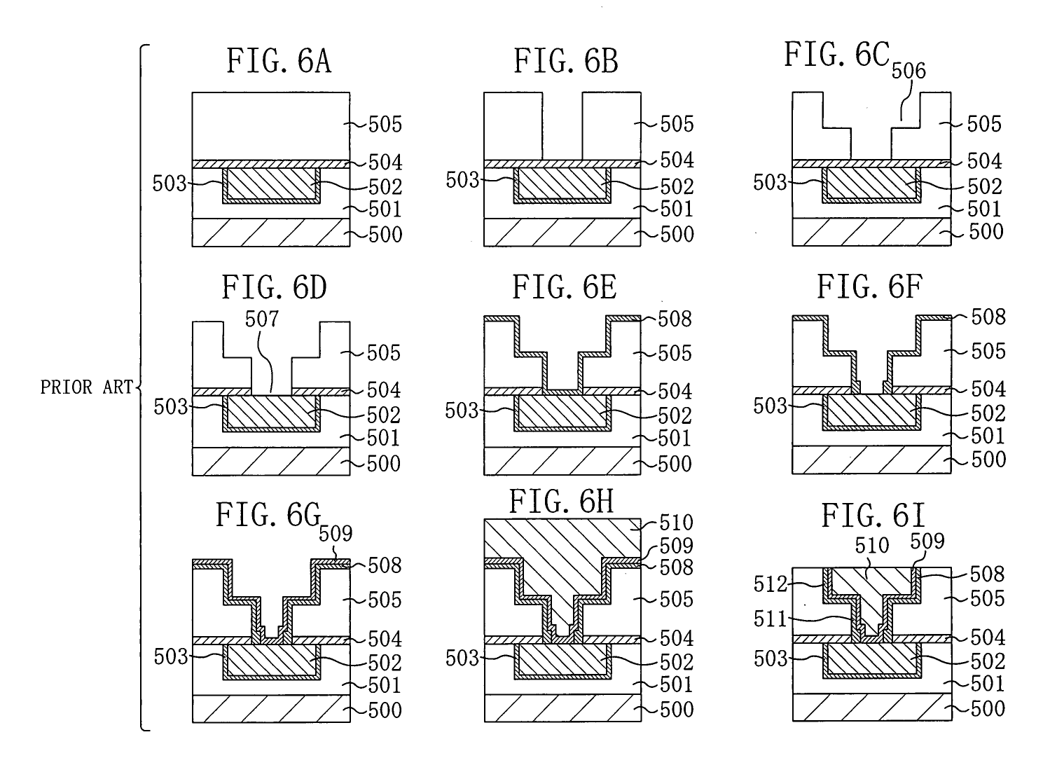

### DESCRIPTION OF THE PREFERRED EMBODIMENT

### Embodiment 1

A semiconductor device and a method for manufacturing it according to Embodiment 1 of the present invention will be described below.

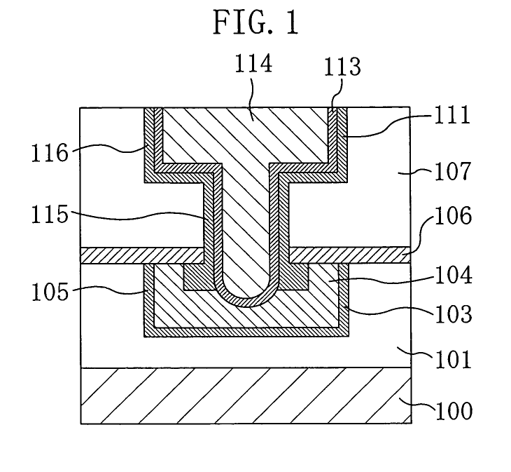

FIG. 1 is a section showing the semiconductor device according to Embodiment 1 of the present invention.

The semiconductor device according to Embodiment 1 of the present invention includes, as shown in FIG. 1, a first interlayer insulating film 101 formed on a semiconductor substrate 100, a first wiring 105 formed of a first barrier metal film 103 and a first Cu film 104 which are formed in the first interlayer insulating film 101, a liner insulating film 106 formed on the first interlayer insulating film 101 and the first wiring 105, a second interlayer insulating film 107 formed on the liner insulating film 106; a plug 115 which is formed of respective parts of a second barrier metal film 111, a third barrier metal film 113, and a second Cu film 114 and which is formed in the second interlayer insulating film 107 so as to stick in the upper part of the first Cu film 104, and a second wiring 116 formed of respective parts on the plug 115 of the second metal film 111, the third barrier metal film 113, and the second Cu film 114.

Herein, in the semiconductor device according to Embodiment, a hollow having a diameter larger than the diameter of the plug 115 is formed in part of the first Cu film 104 under the liner insulating film 106, and the second barrier metal film 111 is formed so as to fill the hollow. The film thickness of part of the second barrier metal film 111 where the hollow is filled is greater than the film thickness of part of the second barrier metal film 111 where it is formed at a side wall of the plug 115. Accordingly, defects is hardly generated at the interface between the liner insulating film 106 and the first interlayer insulating film 101, increasing resistance to stress migration.

Only the third barrier metal film 113 lies at the contact part between the plug 115 and the first wiring 105 while the second barrier metal film 111 and the third barrier metal film 113 are formed at the side wall of the plug 115 and the side wall and the bottom part of the second wiring 116. This ensures the contact area between the plug 115 and the first wiring 105, suppressing an increase in wiring resistance. Further, electric field concentration in current flowing between the wirings is reduced to suppress the electro-migration.

The total thickness of the barrier metal films is approximately 2 nm at the contact part between the plug 115 and the first wiring 105, approximately 10 nm at the part where the hollow is filled, and approximately 4 nm at the side wall of the plug 115 and the side wall and the bottom part of the second wiring 116.

The plug 115 formed so as to stick in the first wiring 105 has a rounded lower part. This shape causes less stress concentration on the second barrier metal film 111 compared with the case where the bottom of the plug 115 is flat.

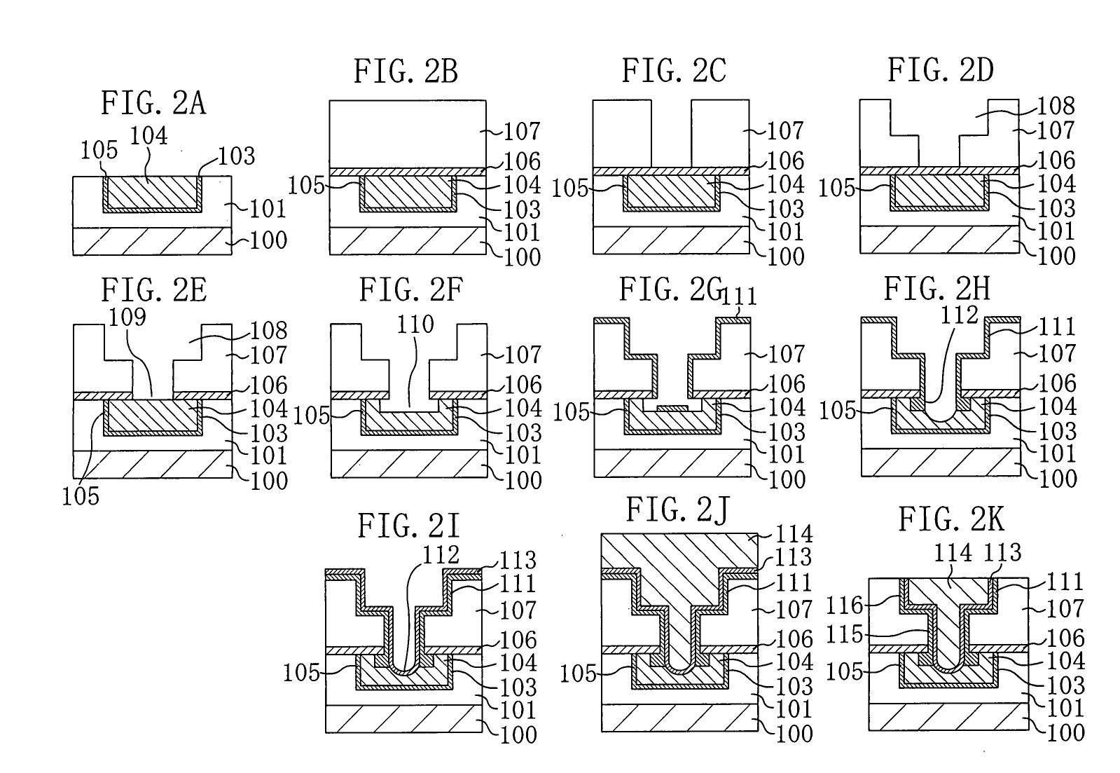

A semiconductor device manufacturing method according to Embodiment 1 of the present invention will be described next. FIG. 2A to FIG. 2K are sections showing the respective steps of the semiconductor device manufacturing method according to Embodiment 1 of the present invention.

First, as shown in FIG. 2A, the first interlayer insulating film 101 is formed on the semiconductor substrate 100 made of silicon (Si) by CVD. Herein, the first interlayer insulating film 101 is a low dielectric film having a dielectric constant of 5 or lower and made of silicon oxide (SiOₓ), carbon doped silicon oxide (SiOC), carbon doped silicon nitride (SiCN), or the like. Next, a first trench is formed in the first interlayer insulating film 101 by dry etching. Herein, the first trench is formed so as to have a depth of 200 nm and a width of 100 nm. Then, the first barrier metal film 103 made of a tantalum nitride (TaN) film and a tantalum (Ta) film and having a thickness of 5 nm is formed on the first interlayer insulating film 101 by sputtering so as to cover the first trench. Next, a seed Cu film (not shown) is formed on the first barrier metal film 103 by sputtering so as to cover the first trench. The first Cu film 104 having a thickness of 400 nm is formed on the seed Cu film by plating so as to fill the first trench. Then, the first Cu film 104 and the first barrier metal film 103 are polished by CMP until the upper face of the first interlayer insulating film 101 is exposed, thereby forming the first wiring 105 formed of the first barrier metal film 103 and the first Cu film 104 in the first trench.

Subsequently, as shown in FIG. 2B, the liner insulating film 106 having a thickness of 50 nm and the second insulating film 107 having a thickness of 400 nm are formed sequentially on the first interlayer insulating film 101 and the first wiring 105 by CVD. Herein, the second interlayer insulating film 107 is a low dielectric film having a dielectric constant of 5 or lower and made of silicon oxide (SiOₓ), carbon doped silicon oxide (SiOC, SiOCN) or the like. The liner insulating film 106 is an insulator having a dielectric constant of 5 or lower and excluding oxygen, such as silicon carbide (SiC), silicon nitride (SiN), silicon nitrocarbide (SiCN), or the like, and is made of a material having dry etching selectivity with respect to the second interlayer insulating film 107.

Next, as shown in FIG. 2C, part of the second interlayer insulating film is removed by dry etching using a photoresist (not shown) as a mask so as to expose the liner insulating film 106. In this dry etching, the liner insulating film 106 functions as an etch stopper.

Thereafter, as shown in FIG. 2D, an upper region of the second interlayer insulating film 107 including part above part where the liner insulting film 106 is exposed is removed by dry etching to form a second trench 108. The second trench 108 is formed so as to have a depth of approximately 200 nm and a width of approximately 100 nm.

Subsequently, as shown in FIG. 2E, the part where the liner insulating film 106 is exposed is removed by dry etching to form a first via 109 with the first Cu film 104 exposed at the bottom of the first via 109.

Next, as shown in FIG. 2F, part of the first Cu film 104 is dissolved using an alkali solution or an acid solution which are capable of dissolving Cu. The dissolution forms, in the first Cu film 104 under the liner insulating film 106, a hollow 110 having a width approximately 10 nm larger than that of the first via 109. The bottom of the hollow 110 is almost flat and has a depth of 10 nm, for example. Herein, an ammonium water having a concentration of 0.1 M is used as the alkali solution, or a nitric acid solution having a concentration of 0.1 M or the like is used as the acid solution. Then, the semiconductor device is subjected to thermal treatment at a temperature in the range between 100° C. and 400° C., both inclusive, in a vacuum. The thermal treatment is performed in an atmosphere capable of reducing the first Cu film 104, such as nitrogen (N₂), hydrogen (H₂), argon (Ar), a gaseous mixture thereof, or the like or in an atmosphere having weak oxidation power.

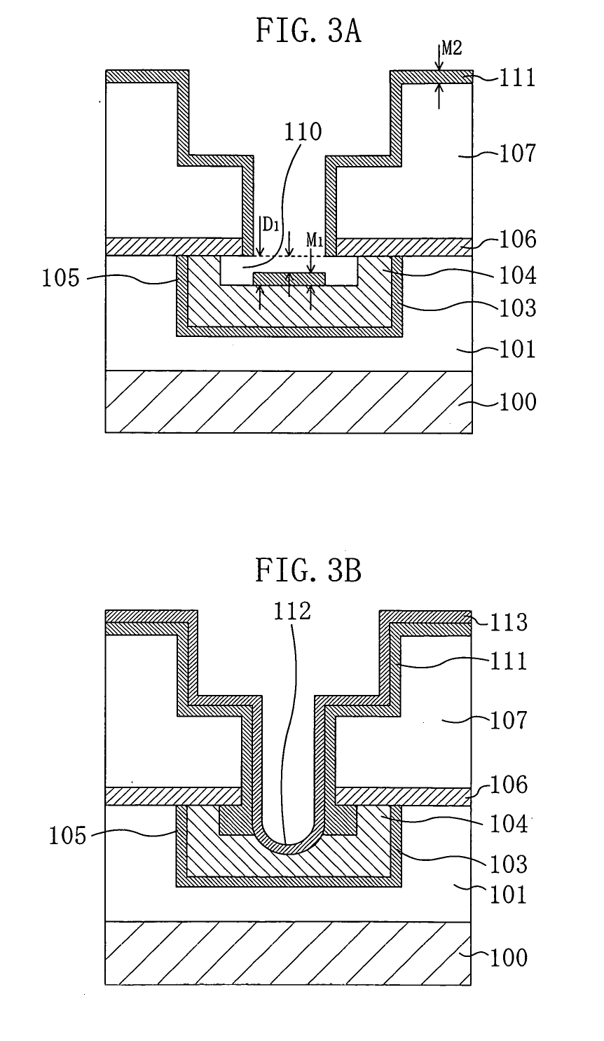

Thereafter, as shown in FIG. 2G, the second barrier metal film 111 made of a TaN film and Ta film is formed by sputtering with the semiconductor device held in the vacuum. The step coverage is low in this formation of the second barrier metal film 111 by sputtering, and therefore, the second barrier metal film 111 is not formed on part of the hollow 110 in the first Cu film 104 under the liner insulating film 106, that is, the side face of the hollow 110 and part of the bottom face of the hollow 110 where the width thereof is greater than the width of the first via 109. Accordingly, the second barrier metal film 111 is formed on the part of the bottom of the hollow 110, the side face of the first via 109, and the side face and the bottom face of the second trench 108. Wherein, as shown in FIG. 3A, the film thickness M₁ of the second barrier metal film 111 on the part of the bottom face of the hollow 110 is greater than the film thickness M₂ of the second barrier metal film 111 on the second interlayer insulating film 107. For example, when the film thickness M₂ of the second barrier metal film 111 on the second interlayer insulating film 107 is 20 nm to 30 nm, the film thickness M₁ of the second barrier metal film 111 on the part of the bottom face of the hollow 110 is 2 nm to 5 nm. The film thickness M₁ of the second barrier metal film 111 on the part of the bottom face of the hollow 110 is smaller than the depth D₁ of the hollow 110. It is noted that the second barrier metal film 111 may be made a metal film having a high melting point, such as a Ta film, a tungsten (W) film, a ruthenium (Ru) film, or the like, a film made of any of the metal films to which nitrogen (N), carbon (C), silicon (Si), or the like is doped, or a laminated film thereof. The second barrier metal film 111 may be formed by CVD.

Subsequently, as shown in FIG. 2H, the second barrier metal film 111 is re-sputtered within the same chamber as that used in the step of forming the second barrier metal film 111 as shown in FIG. 2G. In this re-sputtering, the second barrier metal film 111 on the part of the bottom face of the hollow 110 is shaved and re-adheres to the side face of the hollow 110 so as to fill the part of the hollow 110 where the width thereof is greater than the width of the first via 109. Further, the re-sputtering shaves part of the first Cu film 104, so that the first via 109 extends to be a second via 112 having a rounded lower part. It is noted that re-sputtering may be performed so that the part of the second barrier metal film 111 under the liner insulating film 106 is aligned with part of the second barrier metal film 111 at the side face of the second via 112, namely, the inner diameter of the second via 112 at part where the hollow 110 is formed is equal to that at part where the hollow 110 is not formed. In this case, the second via 112 is readily filled with Cu.

Next, as shown in FIG. 2I, the third barrier metal film 113 having a thickness of 2 nm is formed by sputtering so as to cover the second via 112 and the second trench 108. By this step, only the third barrier metal film 113 lies on the bottom face of the second via 112, as shown in FIG. 3B, and therefore, the film thickness of part of the barrier metal film which is on the bottom face of the second via 112 is smaller than the film thickness of the other part of the barrier metal film where the second barrier metal film 111 and the third barrier metal film 103 are formed, specifically, the respective parts thereof on the second interlayer insulating film 107, on the side face of the second via 112, on the side face and the bottom face of the trench 108.

Thereafter, as shown in FIG. 2J, the seed Cu film (not shown) having a thickness of 40 nm is formed on the third barrier metal film 113 by sputtering so as to cover the second via 112 and the second trench 108. The seed Cu film may be formed by CVD. Then, the second Cu film 114 is formed on the seed Cu film by electrolytic plating so as to fill the second via 112 and the second trench 108. It is noted that the seed Cu film may be made of an alloy of Cu and another metal. Further, electroless plating may be employed rather than electrolytic plating.

Subsequently, as shown in FIG. 2K, the second Cu film 114, the third barrier metal film 113, and the second barrier metal film 111 are polished by CMP until the upper face of the second interlayer insulating film 107 is exposed. Thus, the plug 115 formed of the second barrier metal film 111, the third barrier metal film 113, and the second Cu film 114 is formed in the second via 112 while the second wiring 116 formed of the second barrier metal film 111, the third barrier metal film 113, and the second Cu film 14 is formed in the second trench 108.

In the semiconductor device manufacturing method according to Embodiment 1 of the present invention, the step of forming the hollow 110 shown in FIG. 2F is provided before the re-sputtering step shown in FIG. 2H, and accordingly, removal of the second barrier metal film 111 on the part of the bottom face of the first via 109 and formation of the second via 112 can be attained in a single step. Further, by the re-sputtering step shown in FIG. 2H, the second barrier metal film 111 adheres to the side face of the hollow 110 under the liner insulating film 106 and fills the part of the hollow 110 where the width thereof is greater than the width of the first via 109, ensuring the contact area between the first wiring 105 and the plug 115.

The liner insulating film 106 prevents the first Cu film 104 from diffusing into the second interlayer insulating film 107

It is noted that Cu is used as a main material of the first wiring 105, the plug 115, and the second wiring 116, but an impurity other than Cu may be doped in part of the wrings or a metal other than Cu may be used for the wirings.

Moreover, in the step shown in FIG. 2F, it is possible that the exposed part of the first Cu film 104 is degenerated by ashing or thermal treatment and the degenerated part is removed with the use of a chemical solution, rather than wet etching using an alkali solution or an acid solution. The ashing or the thermal treatment is performed in an oxygen atmosphere or a fluorine atmosphere. In the case, for example, where the semiconductor device is ashed in an O₂ atmosphere, the exposed part of the first Cu film 104 is oxidized. When the oxidized part is removed with the use of an acid cleaning solution (a diluted sulfuric acid, for example), the hollow 110 is formed. This scheme attains adjustment of the oxidization amount of the first Cu film 104 according to the ashing time, facilitating formation of the hollow 110 as designed.

### Embodiment 2

A semiconductor device and a method for manufacturing it according to Embodiment 2 of the present invention will be described below.

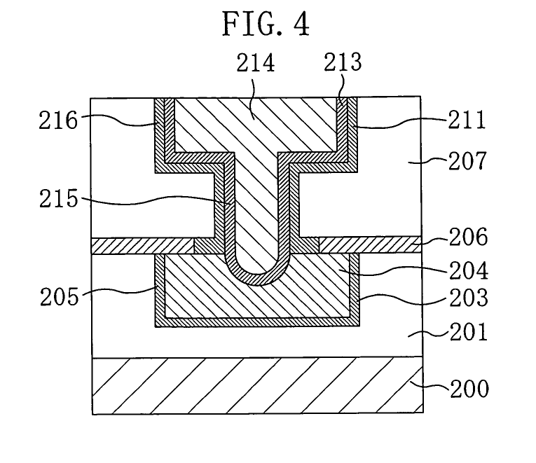

FIG. 4 is a section showing the semiconductor device according to Embodiment 2 of the present invention. The semiconductor device according to Embodiment 2 of the present invention includes a first interlaying insulating film 201 formed on a semiconductor substrate 200, a first wiring 205 formed of a first barrier metal film 203 and a first Cu film 204 which are formed in the first interlayer insulating film 201, a liner insulating film 206 formed on the first interlayer insulating film 201 and the first wiring 205, a second interlayer insulating film 207 formed on the liner insulating film 206, a plug 215 which is formed of respective parts of a second barrier metal film 211, a third barrier metal film 213, and a second Cu film 214 and which is formed in the second interlayer insulating film 207 so as to stick in the upper part of the first Cu film 204, and a second wiring 216 formed of respective parts on the plug 215 of the second metal film 211, the third barrier metal film 213, and the second Cu film 214.

Herein, in the semiconductor device according to Embodiment 2, a hollow (a setback part) having a diameter larger than the plug 215 is formed in the liner insulating film 206, and the second barrier metal film 211 is formed so as to fill the hollow. The film thickness of part of the second barrier metal film 211 where the hollow is filled is greater than the film thickness of part of the second barrier metal film 211 where it is formed at a side wall of the plug 215. With this structure, defects is hardly generated at the interface between the liner insulating film 206 and the first interlayer insulating film 201, increasing the resistance to stress migration.

Further, only the third barrier metal film 213 lies at the contact part between the plug 215 and the first wiring 205, and the second barrier metal film 211 and the third barrier metal film 213 are formed at the side wall of the plug 215 and the side wall and the bottom part of the second wiring 216. Accordingly, the contact area between the plug 215 and the first wiring 205 can be ensured, suppressing an increase in the wiring resistance. Further, electric field concentration in current flowing between the wirings is reduced, suppressing electro-migration.

The total thickness of the barrier metal films is approximately 2 nm at the contact part between the plug 215 and the first wiring 205, approximately 10 nm at the part where the hollow is filled, and approximately 4 nm at the side wall of the plug 215 and the side wall and the bottom part of the second wiring 216.

The plug 215 formed so as to stick in the first wiring 205 has a rounded lower part. This shape causes less stress concentration on the second barrier metal film 211 compared with the case where the bottom of the plug 215 is flat.

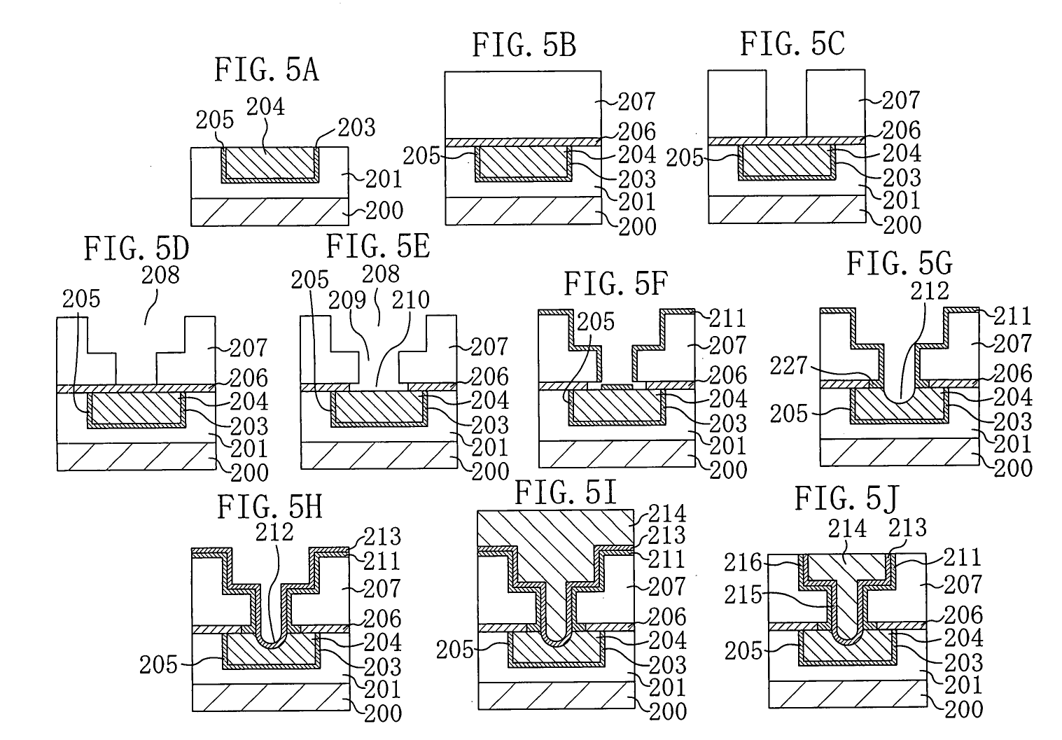

FIG. 5A to FIG. 5J are sections showing the respective steps of the semiconductor device manufacturing method according to Embodiment 2 of the present invention.

First, as shown in FIG. 5A, by the same scheme as the scheme described in Embodiment 1, the first interlayer insulating film 201 is formed on the semiconductor substrate 200, and the first wiring 205 formed of the first barrier metal film 203 and the first Cu film 204 is formed in the first interlayer insulating film 201.

Subsequently, as shown in FIG. 5B, the liner insulating film 206 having a thickness of 30 nm and the second interlayer insulting film 207 are formed sequentially on the first interlayer insulating film 201 including the first wiring 205 by CVD. Herein, in the method according to Embodiment 2 of the present invention, the liner insulating film 206 is made of a material having selectivity with respect to the first Cu film 204 and the second interlayer insulating film 207. For example, SiC containing much carbon and the like may be listed as the material of the liner insulating film 206.

Next, as shown in FIG. 5C, part of the second interlayer insulating film 207 is removed by dry etching using a photoresist (not shown) as a mask so as to expose the liner insulating film 206. In this dry etching, the liner insulating film 206 functions as an etch stopper.

Thereafter, as shown in FIG. 5D, an upper region of the second interlayer insulating film 207 including part above part where the liner insulting film 206 is exposed is removed by dry etching to form a second trench 208 and a first via 209. The second trench 208 is formed so as to have a depth of approximately 200 nm and a width of approximately 100 nm.

Subsequently, as shown in FIG. 5E, dry etching is performed in an atmosphere of which N₂ or O₂ ratio is increased to form a hollow 210 having a width larger than that of the first via 209 in the liner insulating film 206. Then, the semiconductor device is subjected to thermal treatment at a temperature in the range 100° C. and 400° C., both inclusive, in a vacuum. The thermal treatment is performed in an atmosphere capable of reducing the first Cu film 204, such as nitrogen (N₂), hydrogen (H₂), argon (Ar), a gaseous mixture thereof, or the like or in an atmosphere having weak oxidation power.

Next, as shown in FIG. 5F, the second barrier metal film 211 made of a TaN film and Ta film is formed by sputtering with the semiconductor device held in the vacuum. The step coverage is low in this formation of the second barrier metal film 211 by sputtering, and therefore, the second barrier metal film 211 is not formed on the side face of the hollow 210 and part of the bottom face of the hollow 210 where the width thereof is greater than the width of the first via 209.

Accordingly, the second barrier metal film 211 is formed on the part of bottom face of the hollow 210, the side face of the first via 209, and the side face and the bottom face of the second trench 208. Wherein, the film thickness of the second barrier metal film 211 on the part of the bottom face of the hollow 210 is smaller than the film thickness of the second barrier metal film 211 on the second interlayer insulating film 207. For example, when the film thickness of the second barrier metal film 211 on the second interlayer insulating film 207 is 20 nm to 30 nm, the film thickness of the second barrier metal film 211 on the part of the bottom face of the hollow 210 is 2 nm to 5 nm. The film thickness of the second barrier metal film 211 on the part of the bottom face of the hollow 210 is smaller than the film thickness of the liner insulating film 206 and the depth of the hollow 210. It is noted that the second barrier metal film 211 may be made a metal film having a high melting point, such as a Ta film, a tungsten (W) film, a ruthenium (Ru) film, or the like, a film made of any of the metal films to which nitrogen (N), carbon (C), silicon (Si), or the like is doped, or a laminated film thereof. The second barrier metal film 211 may be formed by CVD.

Thereafter, as shown in FIG. 5G, the second barrier metal film 211 is re-sputtered within the same chamber as that used in the step of forming the second barrier metal film 211 as shown in FIG. 5F. In this re-sputtering, the second barrier metal film 211 on the part of the bottom face of the hollow 210 is shaved and re-adheres to the side face of the hollow 210 so as to fill the part of the hollow 210 where the width thereof is greater than the width of the first via 209. Further, the re-sputtering shaves the upper part of the first Cu film 204, so that the first via 209 extends to be a second via 212 having a rounded lower part. It is noted that re-sputtering may be performed so that part of the second barrier metal film 211 where the hollow 210 is filled is aligned with part of the second barrier metal film 211 at the side face of the second via 212, namely, the inner diameter of the second via 212 at part where the hollow 210 is formed is equal to that at part where the hollow 210 is not formed. In this case, the second via 212 is readily filled with Cu.

Subsequently, as shown in FIG. 2H, the third barrier metal film 213 having a thickness of 2 nm is formed by sputtering so as to cover the second via 212 and the second trench 208. By this step, only the third barrier metal film 213 lies on the bottom face of the second via 212, and therefore, the film thickness of part of the barrier metal film which is on the bottom face of the second via 212 is smaller than the film thickness of the other part of the barrier metal film where the second barrier metal film 211 and the third barrier metal film 213 are formed, specifically, the respective parts thereof on the second interlayer insulating film 207, on the side face of the second via 212, on the side face and the bottom face of the trench 208.

Next, as shown in FIG. 5I, the seed Cu film (not shown) having a thickness of 40 nm is formed on the third barrier metal film 213 by sputtering so as to cover the second via 212 and the second trench 208. The seed Cu film may be formed by CVD. Then, the second Cu film 214 is formed on the seed Cu film by electrolytic plating so as to fill the second via 212 and the second trench 208. It is noted that the seed Cu film may be made of an alloy of Cu and another metal. Further, electroless plating may be employed rather than electrolytic plating.

Thereafter, as shown in FIG. 2J, the second Cu film 214, the third barrier metal film 213, and the second barrier metal film 211 are polished by CMP until the upper face of the second interlayer insulating film 207 is exposed. Thus, the plug 215 formed of the second barrier metal film 211, the third barrier metal film 213, and the second Cu film 214 is formed in the second via 212 while the second wiring 216 formed of the second barrier metal film 211, the third barrier metal film 213, and the second Cu film 214 is formed in the second trench 208.

In the semiconductor device manufacturing method according to Embodiment 2 of the present invention, the step of forming the hollow 210 shown in FIG. 5E is provided before the re-sputtering step shown in FIG. 5G, and accordingly, removal of the second barrier metal film 211 on the part of the bottom face of the first via 209 and formation of the second via 212 can be attained in a single step. Further, by the re-sputtering step shown in FIG. 5G, the second barrier metal film 211 adheres to the side face of the hollow 210 and fills the part of the hollow 210 where the width thereof is greater than the width of the first via 209, ensuring the contact area between the first wiring 205 and the plug 215.

The liner insulating film 206 prevents the first Cu film 204 from diffusing into the second interlayer insulating film 207

It is noted that Cu is used as a main material of the first wiring 205, the plug 215, and the second wiring 216, but an impurity other than Cu may be doped in part of the wirings, or a metal other than Cu may be used for the wirings.

In the semiconductor device manufacturing method according to Embodiment 2 of the present invention, the downwardly protruding second via 212 at the bottom of which the first Cu film 204 and the third barrier metal film 213 are in contact with each other can be formed deeper than that formed by the semiconductor device manufacturing method according to Embodiment 1, with a result that the contact area between the first Cu film 204 and the third barrier metal film 213 increases, reducing the electric resistance.

As described above, the present invention is useful for semiconductor devices having buried wiring formed by a damascene process and a method for manufacturing it.

What is claimed is:

1. A semiconductor device comprising:
a fist insulting film formed on a semiconductor substrate;
a first wiring formed in the first insulating film;
a second insulting film formed on the first insulating film; and
a plug formed in the second insulating film,
wherein the plug is formed so as to stick in the first wiring and is formed of a first barrier film, a second barrier film, and a metal film,
a hollow of which diameter is larger than that of the plug is formed in the first insulating film under the second insulating film,
the first barrier film forms a side wall of the plug and fills the hollow, and
the second barrier film is formed along the first barrier film so as to cover the metal film at the side wall of the plug and at a part where the plug is in contact with the first wiring.

2. The semiconductor device of claim 1,
wherein a film thickness of part of the first barrier film where the hollow is filled is greater than a film thickness of part of the first barrier film at the side wall of the plug.

3. The semiconductor device of claim 1, further comprising:
a second wiring formed on the plug in the second insulating film.

4. The semiconductor device of claim 1,
wherein the second insulating film includes a liner film and an interlayer insulating film formed on the liner film.

5. A semiconductor device comprising:
a first insulating film formed on a semiconductor substrate;
a first wiring formed in the first insulating film;
a second insulating film formed on the first insulating film;
a third insulating film formed on the second insulating film; and
a plug formed in the second insulating film and the third insulating film,
wherein the plug is formed so as to stick in the first wiring and is formed of a first barrier film, a second barrier film, and a metal film,
the second insulating film is set back largely from the periphery of the plug,
the first barrier film forms a side wall of the plug and fills the setback part of the second insulating film, and
the second barrier film is formed along the first barrier film so as to cover the metal film at the side wall of the plug and at a part where the plug is in contact with the first wiring.

6. The semiconductor device of claim 5,
wherein a film thickness of part of the first barrier film where the setback part is filled is greater than a film thickness of part of the first barrier film at the side wall of the plug.

7. The semiconductor device of claim 5, further comprising:
a second wiring formed on the plug in the second insulating film.

8. The semiconductor device of claim 5,
wherein the second insulating film is made of a material having etching selectivity with respect to the first wiring and the third insulating film.

9. A method for manufacturing a semiconductor device, comprising the steps of:
(a) forming a first trench in a first insulating film formed on a semiconductor substrate and forming, in the first trench, a first wiring formed of a barrier film and a first metal film;
(b) forming a second insulating film on the first insulating film;
(c) forming a second trench by removing the second insulating film so as to expose the first metal film;
(d) forming a hollow having a diameter larger than that of the second trench by removing an upper part of the first metal film which is exposed at the second trench;
(e) forming a first barrier film so as to cover part of a bottom face of the hollow and a side face of the second trench;
(f) depositing the first barrier film on a side face of the hollow by removing the first barrier film on the bottom face of the hollow;
(g) forming a second barrier film so as to cover the hollow and the second trench over the first barrier film;
(h) forming a second metal film so as to fill the hollow and the second trench over the second barrier film; and
(i) forming a plug by removing the second metal film, the second barrier film, and the first barrier film so as to expose the second insulating film.

10. A method for manufacturing a semiconductor device, comprising the steps of:
(a) forming a first trench in a first insulating film formed on a semiconductor substrate and forming, in the first trench, a first wiring formed of a barrier film and a first metal film;
(b) forming, on the first insulating film, a second insulating film and a third insulating film sequentially;
(c) forming a second trench by removing part of the second insulating film and the third insulating film so as to expose the first metal film;
(d) forming a hollow having a diameter larger than that of the second trench by setting back the second insulating film;
(e) forming a first barrier film so as to cover a bottom face of the hollow and a side face of the second trench;
(f) depositing the first barrier film on a side face of the hollow by removing the first barrier film on the bottom face of the hollow;
(g) forming a second barrier film so as to cover the hollow and the second trench over the first barrier film;
(h) forming a second metal film so as to fill the hollow and the second trench over the second barrier film; and
(i) forming a plug by removing the second metal film, the second barrier film, and the first barrier film so as to expose the second insulating film.

11. The method of claim 10, further comprising the step of:
(x) forming a third trench above the first wiring in the second insulating film before the step (c),
wherein in the step (c), the second trench is formed under the third trench,
in the step (e), the first barrier film is formed so as to cover also a side face and a bottom face of the third trench,
in the step (g), the second barrier film is formed so as to cover also the side face and the bottom face of the third trench,
in the step (h), the second metal film is formed so as to fill also the third trench, and
in the step (i), a second wiring is also formed.

12. The method of claim 10,
wherein in the step (d), the hollow is formed in such a manner that an upper part of the first metal film exposed at the second trench is oxidized and the oxidized part is removed by cleaning.

13. The method of claim 10,
wherein in the step (d), the hollow is formed in such a manner that an upper part of the first metal film exposed at the second trench is subjected to thermal oxidation and the oxidized part is removed by cleaning.

14. The method of claim 10,
wherein in the step (d), the hollow is formed in such a manner that an upper part of the first metal film exposed at the second trench is oxidized by ashing and the oxidized part is removed by cleaning.

15. The method of claim 10,
wherein in the step (d), the hollow is formed in such a manner that an upper part of the first metal film exposed at the second trench is removed by wet etching using an acid solution or an alkali solution.

16. The method of claim 9,
wherein in the step (e), a film thickness of the first barrier film on the bottom face of the hollow is smaller than a depth of the hollow.

17. The method of claim 10,
wherein in the step (e), a film thickness of the first barrier film on the bottom of the hollow is smaller than a film thickness of the second insulating film.

18. The method of claim 10,
wherein in the step (f), a film thickness of the first barrier film by deposition on a side face of the hollow is greater than a film thickness of the first barrier film on the side face of the second trench.

19. The method of claim 10,
wherein the step (f) is performed so that an inner diameter of the hollow is equal to an inner diameter of the second trench.
